(19) United States
(12) Patent Application Publication
(10) Pub. No.: US 2013/0215589 A1
(43) Pub. Date: Aug. 22, 2013

(54) DEVICES FOR ACCESSORY INTEGRATION

(71) Applicants: Edward Nowak, West Bend, WI (US); Kenneth G. Seidl, Port Washington, WI (US); Paul F. Stangl, West Bend, WI (US)

(72) Inventors: Edward Nowak, West Bend, WI (US); Kenneth G. Seidl, Port Washington, WI (US); Paul F. Stangl, West Bend, WI (US)

(73) Assignee: Raffel Systems, LLC, Germantown, WI (US)

(21) Appl. No.: 13/400,485

(22) Filed: Feb. 20, 2012

(51) Int. Cl. H05K 7/02

(52) U.S. Cl. 361/807

(57) ABSTRACT

The invention provides devices for integration of accessory devices, and systems employing such devices. In particular embodiments, devices described herein provide structural support for and/or electrical power to accessory devices.

### FIELD OF THE INVENTION

The invention provides devices for integration of accessory devices into structures, and systems employing such devices. In particular, the invention provides devices that provide structural support for, electrical power to, and/or data transfer to/from accessory devices.

### BACKGROUND

Convenient access to devices and other useful objects provides efficiency for a user.

### SUMMARY OF THE INVENTION

The invention provides devices for integration of accessory devices into structures, and systems employing such devices. In particular, the invention provides devices that provide structural support for, electrical power to, and/or data transfer to/from accessory devices. In some embodiments, the present invention provides a device comprising: a grommet (e.g., wherein the grommet comprises a distal end, a proximal end, and a hollow portion extending from the proximal end to the distal end); a functional element (e.g., wherein functional element is attached to and/or integrated into a portion of the grommet (e.g., the distal end of the grommet)); a power supply; and an electrical connection (e.g., wherein the electrical connection attaches to and/or extends through the grommet (e.g., a hollow portion of the grommet). In some embodiments, the electrical connection provides a connection between the power supply and the functional element. The invention is not limited by the type or source of power supply. Indeed, any type or source of power supply known in the art may be utilized. In some embodiments, the power supply is a low voltage power adapter. Similarly, the invention is not limited but the type of functional element. In some embodiments, the functional element comprises one or more structural and/or electrical elements. In some embodiments, the functional element comprises a structural element configured for supporting an accessory device and an electrical element for delivering electricity to the accessory device. Similarly, the invention is not limited by the type of accessory device. Indeed, a variety of accessory devices find use within a device of the invention, including, but not limited to: a mobile device, a monitor, a television, a computer, a tablet, a telephone, a light, a personal digital assistant, and a remote control. In some embodiments, the functional element comprises one or more structural and/or electrical components, selected from: a table, a monitor or television stand, a laptop stand, a mobile device holder, a beverage holder, a heating device, a cooling device, a remote control charger, a remote control holder, accent lighting, a vacuum, a massage device, a lumbar support element, a laptop charger, a mobile device charger, a USB port, a light, a speaker, a microphone, an electric socket, etc. In some embodiments, the grommet is configured so as to integrate the device into an object. The invention is not limited by the type of object into which a device is integrated. In some embodiments, the object is: a chair, a couch, a sofa, a loveseat, a table, theater seating, conference seating, wheelchair, hospital bed, a wall, a car (e.g., an armrest, console, dashboard, or other car component), an ambulance, a boat, a plane, a train, medical equipment, etc. In some embodiments, the functional element is configured so as to extend away from the grommet. In some embodiments, electrical connection comprises two or more separable power connection elements (e.g., wherein the separable power connection elements connect end to end and provide an electrical connection between the power supply and the functional element).

In some embodiments, the invention provides an integrated system comprising: a device comprising a grommet described herein, and a structure. The device is not limited to any particular configuration of the device and structure. I some embodiments, the device is integrated within the structure such that the functional element resides on the exterior surface at a first location on the structure, the power supply resides at a second location on or within the structure, and the electrical connection traverses an interior position of the structure. In some embodiments, the structure is: a piece of furniture, a vehicle, and/or a building. In some embodiments, the structure is a piece of furniture selected from a chair, a desk, theater seating, conference seating, a table, a couch, a loveseat, an entertainment system, and/or a bookcase. In some embodiments, the first location is selected from an arm rest, console, desktop, work surface, dashboard, bulk head, head rest, and/or observable surface location. In some embodiments, the second location is selected from the rear, bottom, underside, inner console, and/or glove compartment.

### BRIEF DESCRIPTION OF THE DRAWINGS

The foregoing summary and detailed description is better understood when read in conjunction with the accompanying drawings which are included by way of example and not by way of limitation.

FIG. 1 shows a portion of an exemplary device of the invention.

FIG. 2 shows an exemplary device of the invention.

FIG. 3 shows an exemplary device in which the functional element comprises a port for inserting a portion of an accessory device.

### DETAILED DESCRIPTION OF THE INVENTION

The invention provides devices for integration of accessory devices, and systems employing such devices. In particular embodiments, devices described herein provide structural support for and/or electrical power to accessory devices. In some embodiments, devices are provided that are integrated into, or that are retrofittable into, a structure (e.g., furniture, vehicle, wall, etc.). In particular embodiments, devices are installed within a structure (e.g., furniture, vehicle, wall, etc.) to present one or more functional elements (e.g., power socket, USB port, mobile device dock, work surface, etc.) of the device at or above the surface of the structure. In certain embodiments, a device traverses the interior of a structure to provide electricity to one or more functional elements displayed thereon. In some embodiments, systems are provided comprising a structure (e.g., furniture, vehicle, wall, etc.) and integrated device.

In some embodiments, a device comprises proximal and distal ends. In some embodiments, the distal end comprises a display portion and/or functional portion of the device. The distal end of the device is mounted in the structure (e.g., furniture, seating, vehicle, etc.) to display one or more functional elements at or above the surface of the structure (e.g., armrest of chair, console of vehicle, etc.). In some embodiments, the proximal end of the device comprises a power supply and/or an electric connection. In certain embodiments, a device comprises a spanning portion that spans/traverses the interior of the structure to connect proximal end (e.g., the power supply, electrical connection) to the distal end (e.g., functional/display portion). In some embodiments, the proximal end and spanning portion are configured to safely (e.g., with minimized heat release, fire risk and/or risk of shock) provide electric power and/or data connection to a functional portion (e.g., without being observable from the exterior of the structure).

In certain embodiments, a device provides ergonomic access to any one or more ports, electrical sockets, adaptors, docks, etc. In some embodiments, the functional element of a device presents a user with one or more ports, electrical sockets, adaptors, docks etc. at the immediate surface of a structure (e.g., piece of furniture) such that a user can insert one or more devices (e.g., for charging, for data transfer, etc.) at an easily accessible location.

The present invention provides devices configured for integrating functional elements into/onto structures (e.g., furniture, vehicles, etc.) such that the functional elements are accessible to users. The scope of the invention is not limited to the functional elements described herein. Indeed, any suitable apparatus or device may be used as a functional element. For example, exemplary functional elements include, but are not limited to: a fan, a phone, a phone holder, a remote control holder, a remote control, a mirror (e.g., makeup mirror, rear-view mirror), dental tools, surgical tools, orthopedic traction, speaker(s), a microphone, a PDA holder, an mp3 player (e.g., IPOD, IPAD), an mp3 holder/dock, a decorative element, a mobile device, a mobile device holder/dock, a picture frame, a note pad, a drink holder, a book holder, a work surface, etc.).

In typical embodiments, a functional element is supported on the surface of a structure (e.g., furniture) by a device described herein. A functional element may also receive electric power and/or a data connection through a device of the present invention.

In some embodiments, the distal end of a device provided herein comprises a grommet for transitioning from the interior of the structure within which a device is installed to the exterior. In some embodiments, when installed within a structure, the proximal end of the grommet resides on the interior of the structure, and the distal end of the grommet resides on the exterior of the structure. In some embodiments, the most distal portion of the grommet comprises a functional element. In some embodiments, the most distal portion of the grommet comprises a functional element attachment site and/or functional element adapter. In some embodiments, the grommet allows for a functional element to stably and reversibly reside at the surface of a structure, e.g., in a location that is ergonomically accessible to a user. In some embodiments, a functional element is stable under forces generated by normal use and/or incidental contact. In certain embodiments, a device provides a stable platform for attachment of functional elements or external devices.

In certain embodiments, devices of the present invention provide for installation mounting, integration, etc. of one or more functional elements (e.g., light, mobile device, monitor, etc.) within/to a structure (e.g. piece of furniture (e.g. chair), wall, hospital bed, vehicle, seating, etc.), apparatus, or element. In some embodiments, a device is installed within furniture (e.g. chair, desk, bed, book case, dresser, etc), seating arrangements (e.g. theater seating, conference seating, etc.), medical equipment (e.g., hospital bed, ambulance, medical cart, etc.) and/or a vehicle (e.g. car, truck, boat, plane, train, etc.). In particular embodiments, when installed and/or mounted in/on a chair, couch, or other form of seating, the device is mounted to present a functional element on the arm rest, head rest, side of chair, console area between seats, etc. In some embodiments, when installed and/or mounted in/on vehicle (e.g. car, truck, boat, plane, train, etc.), the device is mounted to present a functional element on the dashboard, overhead, on a console, on a door, on an armrest, along the seat back, etc.

In certain embodiments, a device is mounted within a structure (e.g., chair) to display one or more functional elements at a first location on the surface of the structure (e.g., armrest), and to display the power supply and/or electric connection element at a second location on the surface of the structure (e.g., bottom, rear, etc.). In some embodiments, the spanning portion (e.g., electric cord) safely and discretely spans the distance between the functional element(s) and power supply, within the structure. The present invention allows functional element(s) to be ergonomically accessed by a user without cords, power supplies, or other essential elements from being observable and/or obstacles.

In some embodiment, a device of the present invention allows for a functional element to be mobile with respect to the structure to which it is attached, without detaching the functional element from the device and/or structure. In certain embodiments, a functional element is capable of extending, retracting, rotating, bending, etc. with respect to the structure and/or grommet. In some embodiments, a device is configured to hold stable the functional element in any suitable positions with respect to the structure and/or grommet. In certain embodiments, a functional element is configured to adopt multiple conformations (e.g. concealed and exposed, active and inactive, stowed and deployed, retracted and extended, concealed and revealed, etc.). In some embodiments, a functional element is configured to adopt multiple intermediate conformations (e.g., any conformation between fully retracted and fully extended). In some embodiments, a functional element is configured to adopt discrete intermediate positions. In some embodiments, a functional element is configured to adopt any position between fully extended and fully retracted.

In some embodiments described herein, devices and systems comprise one or more power supplies. As used herein, “power supply” refers to a device, or portion thereof, or means, that supplies electrical energy to one or more electric loads (e.g., functional elements). In particular embodiments, a power supply converts one form of electrical energy (e.g., AC to DC, high voltage to low voltage, etc.) to another. In other embodiments, a power supply converts one type of energy (e.g., mechanical, chemical, solar) into electrical energy (e.g., for use by a functional element). In some embodiments, a power supply (e.g., power cord) is attached (e.g., electrically attached) to an energy source (e.g., plugged into a standard electrical socket, attached to a battery). The invention is not limited by the source for which a power supply obtains energy from. Indeed, a variety of power sources find use within the invention, including, but not limited to: electrical energy transmission systems (e.g., AC line voltage), energy storage devices (e.g., batteries, fuel cells, etc.), electromechanical systems (e.g., generator, alternator, etc.), solar power, etc.

In some embodiments, a power supply is a regulated power supply. A regulated power supply controls the output voltage or current to a specific value. In particular embodiments, the controlled voltage and/or current output by a power supply is held nearly constant (e.g., despite variations in either load current or the voltage supplied by the power supply's energy source). In certain embodiments, a power supply is a linear regulator. In other embodiments, a power supply is a low voltage power adapter. In some embodiments, a power supply outputs AC electricity at a voltage of less than about 1000 Vᵣₘₛ (e.g., less than about 1000 Vᵣₘₛ, less than about 750 Vᵣₘₛ, less than about 500 Vᵣₘₛ, less than about 250 Vᵣₘₛ, less than about 100 Vᵣₘₛ, less than about 50 Vᵣₘₛ). In some embodiments, a power supply outputs DC electricity at a voltage of less than about 1500 V (e.g., less than about 1500 V, less than about 1250 V, less than about 1000 V, less than about 750 V, less than about 500 V, less than about 250 V, less than about 125 V,).

In some embodiments, the invention provides a spanning portion that traverses the interior of a structure in which a device is installed (e.g., connecting the power supply to the grommet and/or functional elements (e.g., directly or indirectly)). In certain embodiments, a spanning portion connects a functional element to one or more elements other than a power supply (e.g., electrical socket, modem (e.g., wired or wireless), router (e.g., wired or wireless), CPU, satellite, telephone line, data line, etc.). In some embodiments, a spanning portion comprises one or more electrical connection elements (e.g., cables, cords, wires, etc.). In some embodiments, a spanning portion delivers electrical energy to power one or more functional elements. In some embodiments, a spanning portion delivers data to and/or from a functional element (e.g., television, monitor, computer, mobile device). In certain embodiments, a spanning portion comprises a data connection and/or electrical connection. In some embodiments, a spanning portion comprises one or more electrical connections (e.g., 1, 2, 3, 4, 5, 6, 7, 8, or more). In some embodiments, a spanning portion comprises one or more data connections (e.g., 1, 2, 3, 4, 5, 6, 7, 8, or more). In some embodiments, a spanning portion comprises connections for delivering data/electricity to specific functional elements (e.g., television, monitor, computer, mobile device, USB port, speaker, etc.). In some embodiments, a spanning portion comprises connections for delivering data/electricity to generic functional elements connected to the distal end of a device of the present invention. In some embodiments, spanning portions are configured to safely transmit electricity and/or data through the interior of a structure (e.g., furniture). In some embodiments, the cords, cables, wires, etc. of the spanning portion are bundled together. In some embodiments, the cords, cables, wires, etc. are contained within a sleeve, lumen, catheter, tube, etc. In some embodiments, cords, cables, wires, etc. are insulated to prevent electrical contact with the structure through which they pass. In some embodiments, cords, cables, wires, etc. are insulated to prevent heating of the structure through which they pass. In some embodiments, a spanning portion is configured to minimize the risk of fire within the structure through which it passes. In some embodiments, a device contains a grommet that allows functional elements and/or wires/cords that provide electricity and/or data to pass through a structure within which the device is mounted. In certain embodiments, when a device is installed on a structure, a grommet provides an opening in the surface of the structure through which functional element(s), structural elements, wires, and/or cords pass. In some embodiments, a device comprises a distal end grommet and a proximal end grommet. In certain embodiments, a distal end grommet provides a mounting surface for functional elements. In particular embodiments, a distal end grommet provides a port for electric and/or data cords. In some embodiments, a proximal end grommet provides a mounting surface for an electrical and/or data port/socket. In certain embodiments, a proximal end grommet provides a port for electric and/or data cords. In other embodiments, a proximal end grommet provides an access point to a power supply.

In certain embodiments, a grommet provides an opening through the surface of a structure in which a device is installed. In some embodiments, a grommet spans a surface that is between 1 mm and 50 cm thick (e.g., about 1 mm . . . about 2 mm . . . about 5 mm . . . about 1 cm . . . about 2 cm . . . about 5 cm . . . about 10 cm . . . about 20 cm . . . about 50 cm), although wider and narrower surfaces may also be spanned by the grommet. In some embodiments, a grommet provides an access port through the surface of a structure, the port being between 1 cm and 20 cm in diameter (e.g., about 1 cm . . . about 2 cm . . . about 5 cm . . . about 10 cm . . . about 20 cm) , although wider and narrower ports may also be used.

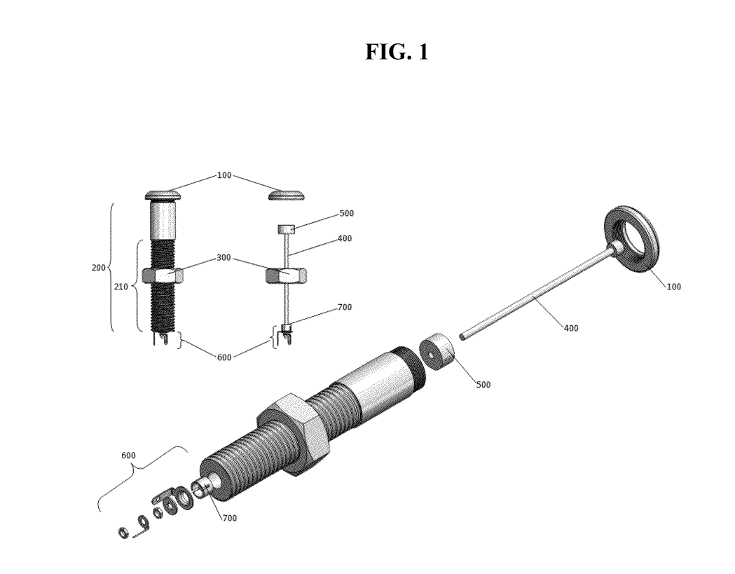

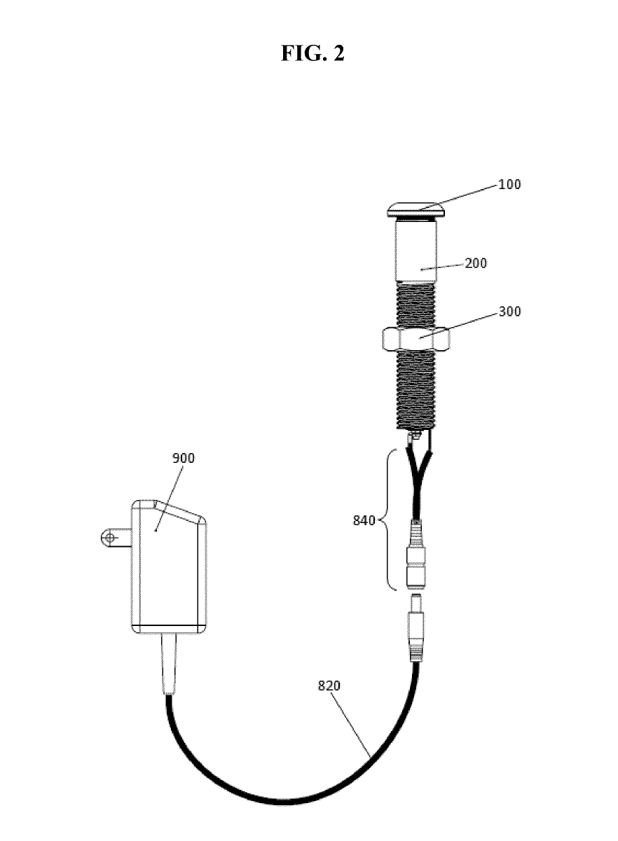

In some embodiments, a device of the invention is secured to and/or within a structure. Devices and systems may comprise one or more securing elements for attaching a device to a structure. In certain embodiments, a grommet securing element 300 (See, for example, FIGS. 1 and 2), is configured to stably attach a grommet 200 to a structure such that the functional element 100 is stably displayed on the exterior of the structure (e.g., at or above the surface). The present invention is not limited by the securing means used for attaching a device to a structure. Indeed, any means known in the art finds use in the invention, including, but not limited to nut and bolt-type elements (See FIG. 1), clips, screws, latches, brads, adhesives, etc. In some embodiments, several different means are employed for securing the different portions of a device to the interior of a structure.

FIG. 1 depicts the distal end of a device of the present invention (e.g., functional element adapter 100, grommet 200, grommet securing element, electric connection 600, etc.). The scope of the invention should not be viewed as limited to the device depicted in FIG. 1. For example, a distal end depicted in FIG. 1 is a portion of the device that is installed within a structure at the point of user access. The device is installed such that the functional element adapter 100 sits on the exterior of the structure while the rest of the grommet 200 and portions of the device more proximal reside within the structure. The bottom of the functional element adapter 100 is held secure against the surface of the structure by tightening the grommet securing element 300 on the securing portion 210 of the grommet 200. The power element 400 (e.g., grommet electrical connection) provides an electrical connection through the center of the grommet 200, thereby electrically linking the functional element adapter 100 to the electric connection 600 on the proximal end of the grommet 200. The proximal isolation element 700 and distal isolation element 500 provide for stable positioning of the power element 400 relative to the grommet 200 and functional element adaptor 100.

FIG. 2 depicts an exemplary device of the invention. The scope of the invention should not be viewed as limited to the device depicted in FIG. 2. The device depicted in the FIG. 2 comprises a power supply 900, grommet 200, functional element 100, grommet securing element 300, electrical cord 820, and electric adapter 840. The power supply 900 is located at the proximal end of the device. The power supply is typically mounted onto or within a structure in such a manner as to be unobservable, discrete, and/or non-obtrusive. In some embodiments, a power supply is located in/on a structure so as to be easily contacted by a power source (e.g. AC line). The grommet 200 and functional elements are typically mounted onto/within a structure so as to be accessible to a user. The grommet 200 extends through the surface of the structure, placing the majority of the grommet 200 within the structure, but placing the functional element 100 at or above the surface of the structure. In some embodiments, a grommet securing element 300 holds the grommet 200 and/or functional element 100 in place. In some embodiments, the grommet and grommet securing element serve to stably position the functional element at or above the surface of the structure in a manner that is easily accessible by a user. In the embodiment depicted in FIG. 2, the electric cord 820 and electric adapter 840 comprise the spanning portion of the device. In such embodiments, the electric cord 820 and electric adapter 840 create an electric connection between the power supply 900 and grommet 200 and/or functional element 100. In other embodiments, a spanning portion may comprise more or fewer elements making up a single linear connection between the power supply 900 and grommet 200 and/or functional element 100. In some embodiments, a spanning portion comprises multiple linear connections between the power supply 900 and grommet 200 and/or functional element 100. As described herein, a spanning portion may also comprise connections between functional elements 100 and portions of the device other than the power supply 900 (e.g., satellite, CPU, modem, router, etc.).

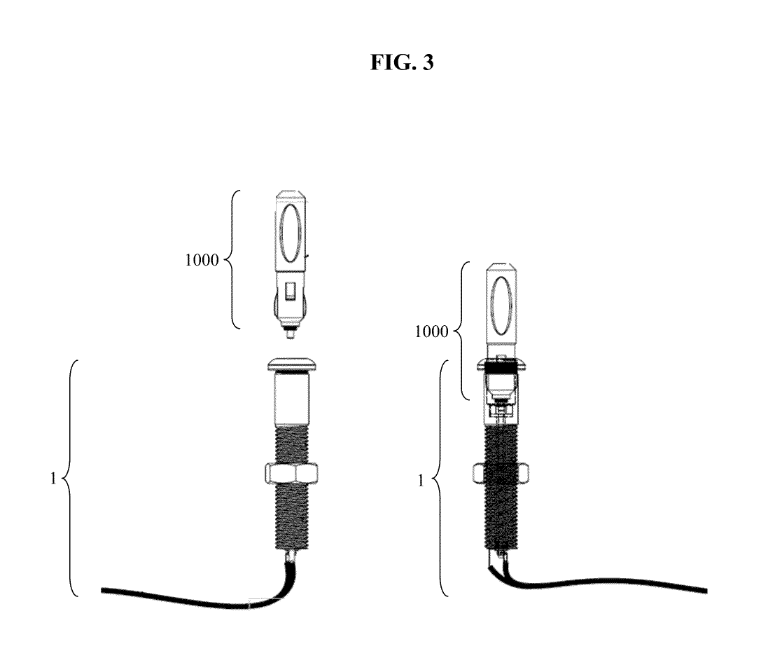

FIG. 3 depicts another embodiment of the invention, in which the functional element of a device 1 comprises a port for inserting a portion of an accessory device 1000. The accessory device 1000 is inserted into an opening in the device 1. In some embodiments, the accessory device receives structural support, electric power, and/or data transfer from its interaction with the device 1. Although not depicted in the figure, in some embodiments, the device 1 is mounted on a structure such that the engaged accessory device 1000 is positioned at the immediate surface of the structure (e.g., for convenient access by a user).

Various modification and variation of the described features and embodiments described herein will be apparent to those skilled in the art without departing from the scope and spirit of the invention. Although specific embodiments have been described, it should be understood that the invention as claimed should not be unduly limited to such specific embodiments. Indeed, various modifications of the described modes and embodiments that are obvious to those skilled in the relevant fields are intended to be within the scope of the following claims.

What is claimed is:

1. A device comprising:
(a) a grommet, wherein said grommet comprises a distal end, a proximal end, and a hollow portion extending from said proximal end to said distal end;
(b) a functional element, wherein said functional element is attached to and/or integrated into the distal end of said grommet;
(c) a power supply; and
(d) an electrical connection, wherein said electrical connection extends through said grommet and provides a connection between said power supply and said functional element.

2. The device of claim 1, wherein said power supply is a low voltage power adapter.

3. The device of claim 1, wherein said functional element comprises one or more structural and/or electrical elements.

4. The device of claim 1, wherein said functional element comprises a structural element configured for supporting an accessory device and an electrical element for delivering electricity to said accessory device.

5. The device of claim 4, wherein said accessory device is selected from the group consisting of: a mobile device, a monitor, a television, a computer, a tablet, a telephone, a light, a personal digital assistant, and a remote control.

6. The device of claim 1, wherein said functional element comprises one or more structural and/or electrical components selected from the group consisting of: a table, a monitor or television stand, a laptop stand, a mobile device holder, a beverage holder, a heating device, a cooling device, a remote control charger, a remote control holder, accent lighting, a vacuum , a massage device, a lumbar support element, a laptop charger, a mobile device charger, a USB port, a light, a speaker, a microphone, and an electric socket.

7. The device of claim 1, wherein said grommet is configured for integrating said device into an object.

8. The device of claim 7, wherein said object is selected from the group consisting of: a chair, a couch, a sofa, a loveseat a table, theater seating, conference seating, wheelchair, hospital bed, a wall, a car, an ambulance, a boat, a plane, a train, and medical equipment.

9. The device of claim 1, wherein said functional element is configured for extension away from said grommet.

10. The device of claim 1, wherein said electrical connection comprises two or more separable power connection elements, and wherein said separable power connection elements connected end to end provide an electrical connection between said power supply and said functional element.

11. The device of claim 1, wherein the electrical connection attaches to and/or extends through a hollow portion of the grommet.

12. A system comprising: (a) a device of claim 1, and (b) structure, wherein said device is integrated within said structure such that said functional element resides on the exterior surface at a first location on said structure, said power supply resides at a second location on and/or within said structure, and said electrical connection that traverses an interior portion of said structure.

13. The system of claim of claim 12, wherein said structure is selected from the group consisting of: a piece of furniture, a vehicle, and a building.

14. The system of claim of claim 13, wherein said structure is a piece of furniture selected from: a chair, a desk, theater seating, conference seating, a table, a couch, a loveseat, an entertainment system, and a bookcase.

15. The system of claim of claim 13, wherein said first location is selected from: an arm rest, console, desktop, work surface, dashboard, bulk head, head rest, and observable surface location.

16. The system of claim of claim 15, wherein said second location is selected from: the rear, bottom, underside, inner console, and glove compartment.

17. The system of claim of claim 15, wherein said second location is a location within the structure.
